(19) United States
(12) Patent Application Publication
(10) Pub. No.: US 2006/0180885 A1
(43) Pub. Date: Aug. 17, 2006

(54) Image sensor using deep trench isolation

(75) Inventor: Howard E. Rhodes, Boise, ID (US)

Correspondence Address: PERKINS COIE LLP / OMNIVISION TECHNOLOGIES, INC., P.O. BOX 1247, SEATTLE, WA, 98111-1247, US

(73) Assignee: OmniVision Technologies, Inc., Sunnyvale, CA (US)

(21) Appl. No.: 11/058,055

(22) Filed: Feb. 14, 2005

(51) Int. Cl. H01L 31/062

(52) U.S. Cl. 257/432

(57) ABSTRACT

An image sensor that has a pixel array formed on a semiconductor substrate is disclosed. The pixel array may also be formed on an epitaxial layer formed on the said semiconductor substrate. A plurality of pixels are arranged in a pattern and formed on the epitaxial layer or directly on the semiconductor substrate. Further, a deep trench isolation formed in the semiconductor substrate, and used to separate adjacent pixels of the plurality of pixels. The deep trench isolation extends through substantially the entire epitaxial layer.

### TECHNICAL FIELD

The present invention relates to image sensors, and more particularly, to image sensors using a deep trench isolation structure to reduce cross-talk between pixels.

### BACKGROUND

Image sensors, whether of the CMOS or CCD variety, are becoming more highly integrated. One result of this higher integration is the reduction of size for each of the pixels in the image sensor. However, it has been found that as image sensor pixel size decreases, the amount of cross-talk between adjacent pixels becomes more of an important issue. In general, cross-talk can be generated from two different sources: (1) optical cross-talk which refers to the ability to optically focus incident light over a pixel through its microlens and onto the appropriate photosensitive element; and (2) electrical cross-talk which refers to the ability to collect the generated photocarriers in the photosensitive element where they are originally generated.

Currently, generated photocarriers (electrons) are not entirely collected in the photosensitive element where they were originally generated. This is because the photogenerated carriers can diffuse to adjacent photosensitive structures. One method to electrically isolate adjacent pixels is to define deep P-well implanted regions around each pixel. The deep P-well regions are electrically connected to the substrate potential and isolate one pixel from another. However, one drawback of this approach is that some incident photons, especially longer wavelength photons, generate electrons deep in the silicon photosensitive element.

To avoid losing the signal from the long wavelength photons, the lightly doped P-type region of the photosensitive element is deep, typically requiring an epitaxial layer thickness that is greater than 4 microns. This results in the isolating deep P-well to be also typically greater than 4 microns, which would require a B11 implant of about 2.4 MeV, which in turn would require a resist thickness of about 8 microns. However, a thick photoresist cannot be used to pattern fine geometries.

As one example of the current state of the art, sub-3 micron pixels have a separation between pixels of about 0.4 microns. Typically, the thickest photoresist that can be used to pattern a 0.4 micron opening is about 2 microns thick. However, a 2 micron thick photoresist will only block a B11 implantation to a maximum energy of about 600 KeV (or about 1 micron depth penetration). A deep P-well isolation that is only 1 micron deep cannot completely isolate the pixels. Further, a lightly doped epitaxial layer having a thickness of 1 micron would degrade the quantum efficiency and the sensitivity of the image sensor. Thus, the current technology is not completely effective and an improved process is advantageous.

### BRIEF DESCRIPTION OF THE DRAWINGS

FIG. 1 is a cross-sectional view of a prior art image sensor illustrating the cross-talk issue.

FIG. 2 is a cross-sectional view of an image sensor showing a first embodiment of the present invention.

FIG. 3 is a cross-sectional view of an image sensor in accordance with an alternative embodiment of the present invention.

FIGS. 4-6 are cross-sectional views showing how the deep trench isolations of the present invention can be formed.

FIGS. 7-8 show cross-sectional illustrations of the steps in forming a deep trench isolation in accordance with an alternative embodiment of the present invention.

### DETAILED DESCRIPTION

In the following description, numerous specific details are provided in order to give a thorough understanding of embodiments of the invention. One skilled in the relevant art will recognize, however, that the invention may be practiced without one or more of the specific details, or with other methods, components, materials, etc. In other instances, well known structures, materials, or operations are not shown or described in order to avoid obscuring aspects of the invention.

References throughout the specification to “one embodiment” or “an embodiment” means that a particular feature, structure, or characteristic described in connection with the embodiment is included in at least one embodiment of the present invention. Thus, the appearances of the phrase “in one embodiment,” or “in an embodiment” in various places throughout the specification are not necessarily all referring to the same embodiment. Furthermore, the particular features, structures, or characteristics may be combined in any suitable manner in one or more embodiments.

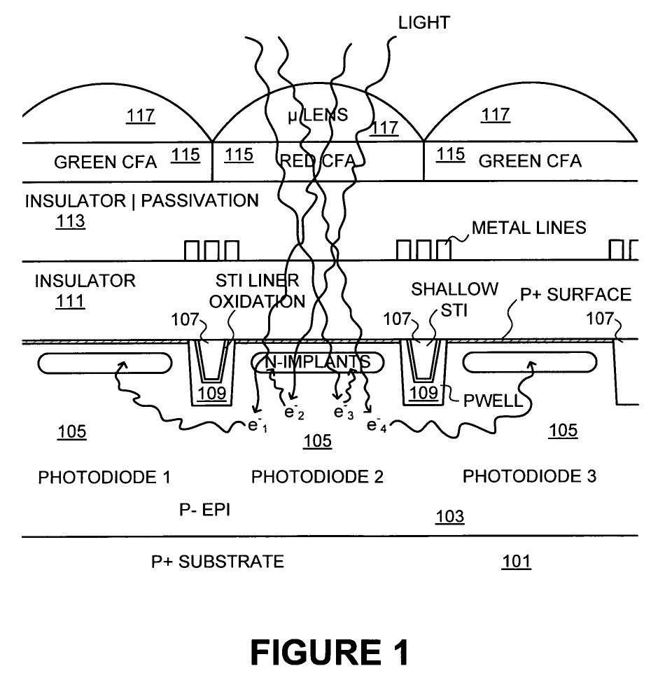

Turning to FIG. 1, a cross-sectional view of a prior art image sensor is shown. In the view of FIG. 1, three adjacent pixels are shown. Note that the precise internal structure of the pixel is not particularly germane to the present invention, and indeed, the present invention may be utilized with any CCD or CMOS pixel design, including but not limited to 3T, 4T, 5T, 6T, 7T, or other pixel designs. Moreover, throughout the description, the term “photosensitive element” is meant to encompass any type of structure that is sensitive to incident radiation, such as, including without limitation, photogates, photodiodes, pinned photodiodes, partially pinned photodiodes, etc. In FIG. 1, the photosensitive element is a photodiode that is formed by an N⁻ implant within the p-type layer or substrate.

As seen in FIG. 1, a P-type substrate 101 has formed thereon a P⁻ epitaxial layer 103. While in this embodiment, a P⁻ epitaxial layer is used, the present invention may also be used where the P⁻ epitaxial layer is omitted. Three pixels are shown in cross-section with prior art shallow trench isolations (STI) 107 used to aid in electrically isolating the photodiodes. However, as noted above, the STIs 107 are insufficient to completely isolate the photodiodes. Further, P-wells 109 are formed to further aid in the isolation. Note that in general, the P-wells 109 extend deeper than the STIs 107. Still, for the reasons noted above, the P-wells 109 are difficult to make deep enough to provide full isolation. Atop the surface of the P⁻ epitaxial layer 103 are conventional insulator layers 111, passivation layer 113, color filter layer 115, and micro lenses 117. These layers are used to focus incident light, implement color image sensors, and provide various interconnect structures and insulation. Further, active structures, such as transistors, within each pixel are not shown for clarity. Note that while the present invention is described in terms of an n-channel transistors formed in a p-type substrate, the dopant types may be changed to accommodate p-channel transistors by using an n-type substrate. Additionally, the present invention is applicable to the formation of deep trench isolations with implanted isolating n-wells in the case where p-channel transistors are used.

Incident light onto the pixel may come in at various angles and because of the particular physical characteristics of the pixels, generated signal in the form of electrons in the photosensitive elements may in fact cause signal to be read out from adjacent pixels. This is the cross-talk issue that the present invention addresses.

To provide some specific context of the prior art, the P⁻ epitaxial layer 103 is typically about 4 microns thick, which is about as thin as the epitaxial layer may be made using current technology. Note that in FIG. 1, light that passes through the red color filter of the center pixel has a longer wavelength and is thus absorbed deeper in the silicon. The created electrons e₁, e₂, e₃, and e₄ are free to diffuse and the diffusion of these electrons is a “random walk.”

In order to address this issue, the present invention uses a deep trench isolation in the image sensor array. The STI technology shown in FIG. 1 is typically on the order of 0.3 to 0.5 microns deep with a P-well 109 that is approximately 1 micron deep. The present invention takes advantage of the selectivity of silicon etching to photoresist erosion to make it possible to generate trenches in the silicon P⁻ epitaxial layer 103 that are relatively deep. The deep trench isolation can be used to isolate a pixel from its adjacent pixels.

As further detailed below, the sidewalls of the trench and the bottom of the trench are implanted in order to passivate the surface states and localized defects and to prevent generation of electrons near the trench. This can be accomplished by implanting the trench with a P-type dopant. For example, in accordance with the present invention, the deep trench isolation may be 4 microns deep. Alternatively, as will be seen further below, a combination of a deep trench isolation and a P-well isolation may be used. Because the depth of the deep trench isolation is much deeper than the prior art, it is less necessary to implant the B11 ion to a depth of 4 microns, and instead, much shallower P-well implants may be used. In other words, because the “starting point” of the implant (the level of the bottom of the deep trench) is deeper, the B11 ions do not need to penetrate into the substrate as deeply.

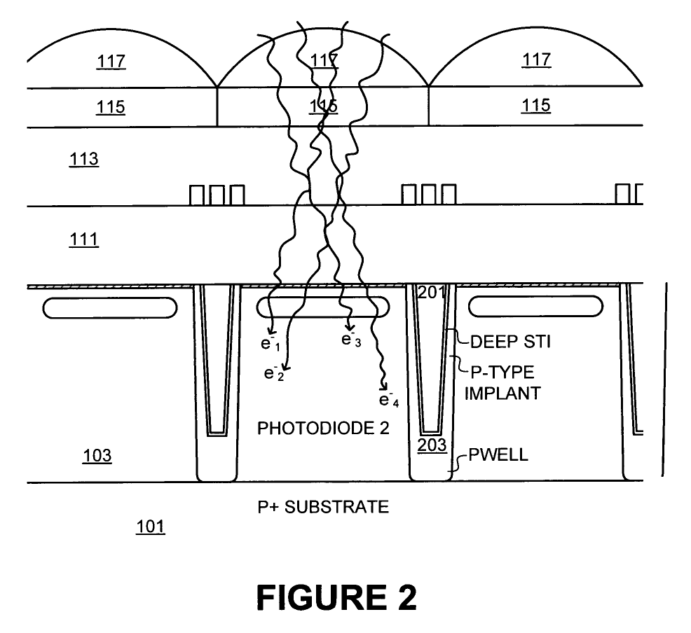

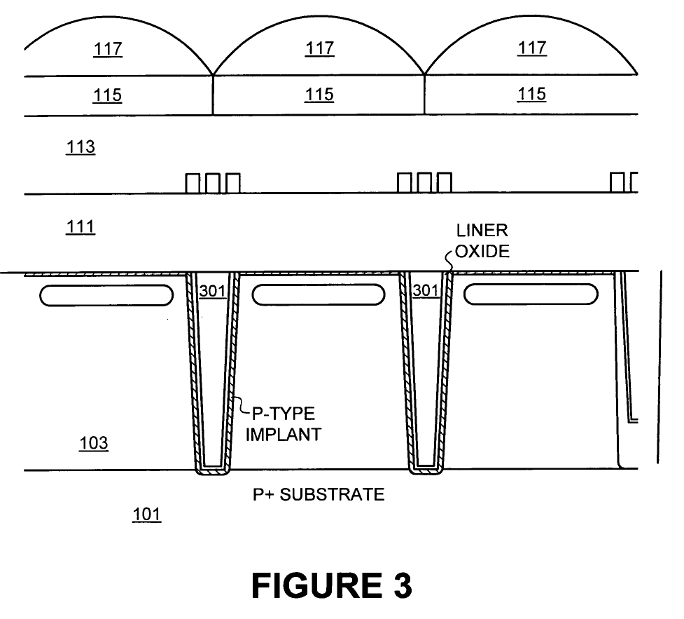

Turning to FIG. 2, a cross-sectional view of an image sensor pixel array showing three pixels and using the deep trench isolation of the present invention is shown. By extending the deep trench isolation 201 down into the epitaxial layer 103, an enhanced isolation can be achieved. Additionally, by forming the deep trench isolation by more deeply etching the epitaxial layer 103, the P-well 203 can be formed using still relatively low implant energies. In one embodiment, the deep trench isolation 201 is on the order of 2 microns deep, but may extend further into the epitaxial layer 103 and even through the epitaxial layer 103 into the substrate 101. In the embodiment shown in FIG. 2, the deep trench isolation does not go all the way to the P substrate layer 101. Turning to FIG. 3, in this alternative embodiment, the deep trench isolation extends all the way to the P-type substrate 101.

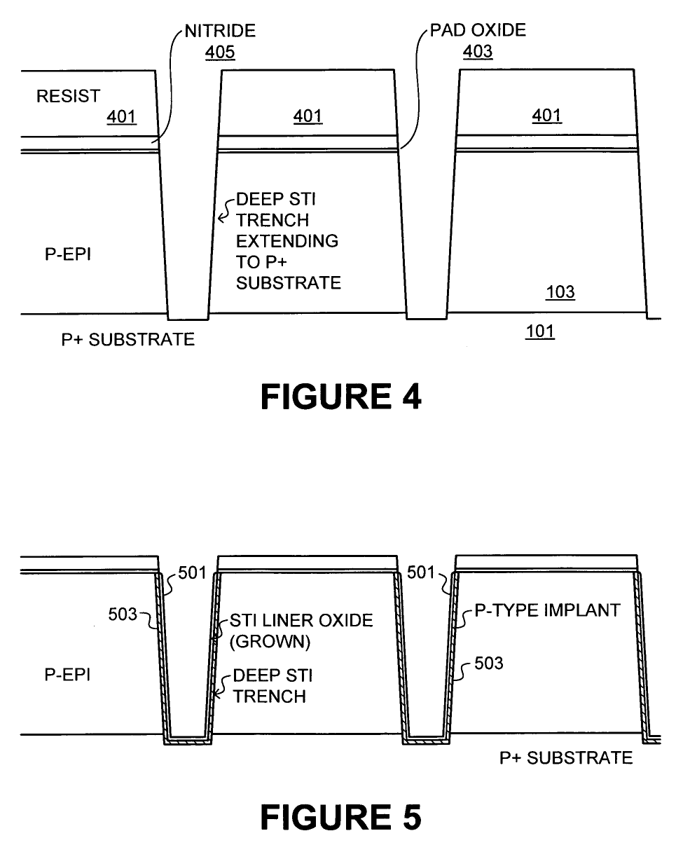

FIGS. 4-6 illustrates a method of forming the embodiment of FIG. 3. Specifically, turning to FIG. 4, after the P³¹ epitaxial layer 103 has been grown or otherwise formed, a photoresist layer 401 is patterned in accordance with the deep trench isolation pattern that separates the pixels. Typically a pad oxide 403 and a nitride layer 405 is formed underneath the photoresist layer 401 and is used in conventional CMOS processes in order to perform various stress relieving, stop layer, and other functions. However, it can be appreciated that other types of intervening layers between the photoresist 401 and the epitaxial layer 103 may be used, and even no intervening layers may be used. Once the photoresist layer 401 has been patterned, an etching step, such as an anisotropic reactive ion etch may be used to etch a trench 407 in the epitaxial layer 103. The trench 407 is deeper than the conventional STIs, and would typically be 1 micron or more in depth.

Next, turning to FIG. 5, the photoresist layer 401 is removed and the image sensor surface is cleaned. Next, a liner oxide layer 501 is grown and a shallow P⁻ implant is performed in order to passivate the surface states and localized defects and to prevent generation of electrons near the trench. In one embodiment, the P-type implant has a dopant concentration of 5e11 to 2e13 ions/cm² and implanted with an energy of 5 to 100 keV. Note that the passivating P⁻ implant is optional. Note that the liner oxide layer 501 is an optional step, as is the shallow P⁻ implant. The liner oxide 501 may be between 20-200 angstroms thick, and further, may be an oxide/nitride stack where the nitride layer is between 20-200 angstroms thick.

Turning to FIG. 6, an oxide is deposited into the deep trench isolation opening. The oxide, in one embodiment may be a high density plasma chemical vapor deposition (HDPCVD) oxide. The HDPCVD oxide is chosen for its ability to fill high aspect ratio openings; however any type of oxide or dielectric may be used to form the deep trench isolation 601. Alternatively, a spin-on-glass (SOG) may be used to fill the deep trench isolation opening. After the formation of the HDPCVD or SOG oxide, a chemical mechanical processing (CMP) step may be used to planarize the surface. Note that the embodiment of FIG. 6 does not require the use of a P-well because of the depth of the deep trench isolation.

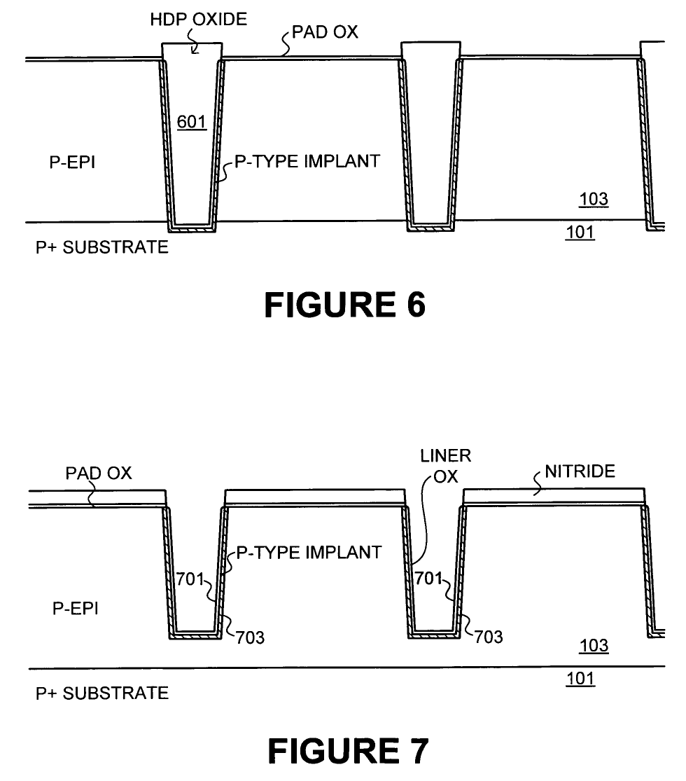

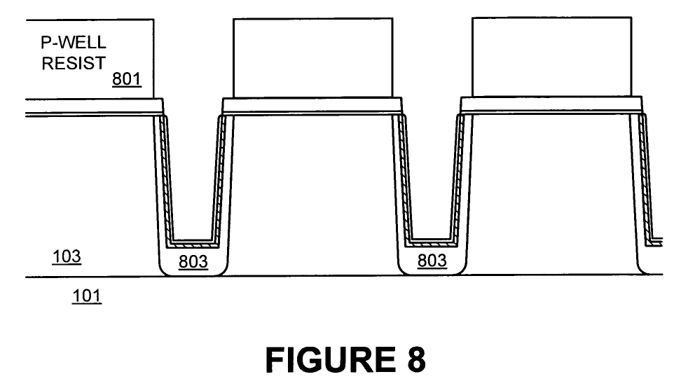

FIG. 7 shows a cross-sectional view of an image sensor pixel array that forms a deep trench isolation that does not extend all the way through the epitaxial layer 103. In this embodiment, the photoresist is patterned as in FIG. 4. However, the epitaxial layer 103 is not etched all the way through and the opening of the trench extends only partially through the epitaxial layer 103. Thus, FIG. 7 is substantially similar to FIG. 5, after the P⁻ implant 703 and the liner oxide layer 701 is formed, except that the trench opening does not extend all the way through the epitaxial layer. Next, turning to FIG. 8, a P-well photomask is formed that will allow a P-well implant to be used that extends the isolation depth to the P-plus substrate 101. Thus, a P-well 803 is formed by the implant, but the implant is performed using a relatively low energy, and generally lower than that of the prior art. In one embodiment, the energy of the implant is on the order of 50 to 500 keV. Thus, in this embodiment, the deep trench isolation is used in combination with the P-well 803.

Note that the deep trench isolation that extends all the way to the substrate 101 may be advantageous in that the P⁻ (FIG. 6) is self-aligned to the deep trench isolation oxide. In the embodiment of FIG. 8, the P-well 803 is not self-aligned to the deep trench isolation. Note further that the deep trench isolation provides a deeper isolation by itself without the use of a P-well. However, for various reasons, the deep trench isolation may be more difficult to manufacture.

Further, the present description only describes the formation of the deep trench isolation and does not go on to describe formation of the actual structures within the pixel, which are well known in the art. This is to avoid obscuring the present invention as the steps in forming the active devices within the pixel are well known in the art.

From the foregoing, it will be appreciated that specific embodiments of the invention have been described herein for purposes of illustration, but that various modifications may be made without deviating from the spirit and scope of the invention. Accordingly, the invention is not limited except as by the amended claims.

I/We claim:

1. A pixel array comprising:
a plurality of pixels arranged in a pattern and formed on an semiconductor substrate;
deep trench isolations formed in said semiconductor substrate, said deep trench isolations separating adjacent pixels of at least a portion of said plurality of pixels, said deep trench isolation extending greater than 1 micron into said semiconductor substrate.

2. The pixel array of claim 1 further including a P-well formed beneath said deep trench isolations.

3. The pixel array of claim 2 wherein said P-well is formed from an implant energy of less than 500 keV.

4. The pixel array of claim 1 further including an epitaxial layer formed over said semiconductor substrate and further wherein said pixels and said deep trench isolations are formed in said epitaxial layer.

5. The pixel array of claim 1 wherein said deep trench isolations have their sidewalls doped with a p-type dopant.

6. The pixel array of claim 1 wherein said deep trench isolation is formed by using a high density plasma chemical vapor deposition (HPDCVD) process or spin-on-glass (SOG).

7. The pixel array of claim 1 wherein said plurality of pixels are 3T, 4T, 5T, 6T, or 7T pixels.

8. The pixel array of claim 1 wherein said semiconductor substrate is n-type.

9. The pixel array of claim 8 further including an N-well formed beneath said deep trench isolations.

10. The pixel array of claim 1 wherein said deep well isolation has a liner layer formed from either oxide or an oxide/nitride stack with a thickness of between 20-200 angstroms.

11. A pixel array comprising:
a semiconductor substrate;
an epitaxial layer formed on said semiconductor substrate;
a plurality of pixels arranged in a pattern and formed on said epitaxial layer;
a deep trench isolation formed in said epitaxial layer, said deep trench isolation separating adjacent pixels of said plurality of pixels, said deep trench isolation extending through substantially the entire epitaxial layer.

12. The pixel array of claim 11 wherein said epitaxial layer is p-type.

13. The pixel array of claim 11 wherein said deep trench isolation has its sidewalls doped with a p-type dopant.

14. The pixel array of claim 11 wherein said deep trench isolation is formed by using a high density plasma chemical vapor deposition (HPDCVD) process or a spin-on-glass (SOG).

15. The pixel array of claim 11 wherein said plurality of pixels are 3T, 4T, 5T, 6T, or 7T pixels.

16. The pixel array of claim 11 wherein said semiconductor substrate is n-type.

17. The pixel array of claim 11 wherein said epitaxial layer and semiconductor substrate is n-type.

18. The pixel array of claim 17 further including an N-well formed beneath said deep trench isolations.

19. The pixel array of claim 11 wherein said deep well isolation has a liner layer formed from either oxide or an oxide/nitride stack with a thickness of between 20-200 angstroms.

20. The pixel array of claim 1 wherein said pixel array is part of a CCD image sensor.
